(19) United States
(12) Patent Application Publication
(10) Pub. No.: US 2006/0091383 A1
(43) Pub. Date: May 4, 2006

(54) SEMICONDUCTOR STRUCTURE AND TESTING METHOD THEREOF

(76) Inventors: Kun-Fu Chuang, Hsinchu (TW); Fu-Chien Chiu, Hsinchu (TW); Ruey-Way Lin, Hsinchu (TW); Jenn-Chang Hwang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/160,689

(22) Filed: Jul. 6, 2005

(30) Foreign Application Priority Data
Oct. 29, 2004 (TW) 93132908

(51) Int. Cl. H01L 23/58

(52) U.S. Cl. 257/48

(57) ABSTRACT

A semiconductor structure and a testing method thereof are provided. The semiconductor structure comprises a substrate, a well, an isothermal heating layer, a first dielectric layer, an interconnection material layer and a second dielectric layer. Wherein, the well is disposed in the substrate, the isothermal heating layer is disposed over the well, the first dielectric layer is disposed between the well and the isothermal heating layer, the interconnection material layer is disposed over the isothermal heating layer, and the second dielectric layer is disposed between the isothermal heating layer and the interconnection material layer. The isothermal heating layer is adapted for maintaining the interconnection metal layer at a predetermined testing temperature so that the testing result can be precise and the testing time can be reduced. Moreover, a low level current can be used as the testing current.

### CROSS-REFERENCE TO RELATED APPLICATION

This application claims the priority benefit of Taiwan application serial no. 93132908, filed on Oct. 29, 2004. All disclosure of the Taiwan application is incorporated herein by reference.

### BACKGROUND OF THE INVENTION

1. Field of the Invention

The present invention relates to a semiconductor structure, and more particularly to a semiconductor structure and a testing method thereof.

2. Description of the Related Art

With advance of semiconductor technology, the size of the semiconductor device for manufacturing integrated circuits is reduced down to 0.25 μm. Correspondingly, the line width of interconnection metal lines must be reduced, and higher integration of devices would result in increased flow of current through interconnection metal lines. When current flow through the interconnection metal lines (wherein the main material of the interconnection metal line is aluminum), aluminum atoms migrate along grain boundaries under the influence of the electrical field generated by the current flow. This phenomenon is called electro-migration.

The electro-migration due to increased current flow is so severe that voids may be formed within the metal line that may be developed into open circuits or cause shorting of other devices in the integrated circuits. Accordingly, how to test the electro-migration effect has become an important subject of reliability of the interconnection metal lines.

Usually, the reliability test of the interconnection metal lines is performed during the wafer manufacturing processes. The earlier package-test is called a Wafer-Level Reliability (WLR) test.

In the present JEDEC test, an isothermal heating current is applied to the interconnection metal layer and it will raise the interconnection metal layer to a predetermined temperature. Thereafter, a testing current is applied to test the interconnection metal layer. Due to the application of the testing current is applied to the interconnection metal layer, the temperature of the interconnection metal layer may fluctuate from the predetermined temperature which renders the test result inaccurate.

The testing time using prior art JESD33-A test is about 500 seconds, and therefore testing time is long and also consumes significant amount of energy.

### SUMMARY OF THE INVENTION

Accordingly, the present invention is directed to a semiconductor structure comprising an isothermal heating layer for maintaining the temperature of the interconnection metal layer at the predetermined temperature during the test.

The present invention is also directed to a method of testing a semiconductor, wherein the directions of flow of the isothermal heating current and the testing current is controlled in an angle to reduce the electromagnetic effects. Furthermore, comparatively lower level of testing current may be used for testing the interconnection metal layer.

The present invention provides a semiconductor structure suitable for testing electro-migration of a substrate's pattern. According to an embodiment of the present invention, the semiconductor structure comprises a well, an isothermal heating layer, a first dielectric layer, an interconnection metal layer and a second dielectric layer. The well is disposed in the substrate. The isothermal heating layer is disposed over the well. The first dielectric layer is disposed between the well and the isothermal heating layer. The interconnection metal layer is disposed over the isothermal heating layer. The second dielectric layer is disposed between the isothermal heating layer and the interconnection metal layer.

The present invention also provides a method of a semiconductor structure. The semiconductor structure at least comprises an isothermal heating layer and an interconnection metal layer. The interconnection metal layer is disposed over the isothermal heating layer. The method of testing the semiconductor structure includes applying an isothermal heating current to the isothermal heating layer and a testing current to the interconnection metal layer to measure the electro-migration of the interconnection metal layer.

According to an embodiment of the present invention, the directions of flow of the isothermal heating current and the testing current is controlled in an angle to reduce the electromagnetic effect of the isothermal heating current and the testing current.

According to an embodiment of the present invention, the isothermal heating layer is adapted for substantially maintaining testing temperature of the interconnection metal layer at a predetermined temperature during the testing process and thus the result of the test can be accurate and the testing time can be reduced. Moreover, comparatively lower level of testing current may be used for testing the interconnection metal layer.

The above and other features of the present invention will be better understood from the following detailed description of the preferred embodiments of the invention that is provided in communication with the accompanying drawings.

### BRIEF DESCRIPTION OF THE DRAWINGS

FIG. 1 is a schematic cross sectional view showing a semiconductor structure according to an embodiment of the present invention.

FIG. 2 is a configuration showing a top view of a semiconductor structure according to an embodiment of the present invention.

FIG. 3 is a top view showing a semiconductor layout top view according to an embodiment of the present invention.

FIG. 4 is a configuration showing a relationship between resistances and temperatures according to an embodiment of the present invention.

FIG. 5 is a flowchart of a testing method for a semiconductor structure according to an embodiment of the present invention.

### DESCRIPTION OF SOME EMBODIMENTS

FIG. 1 is a schematic cross sectional view showing a semiconductor structure according to an embodiment of the present invention. Referring to FIG. 1, the semiconductor 100 is used for testing electro-migration of a pattern (not shown) formed on the substrate 102. The semiconductor structure 100 is described as follows.

In this embodiment of the present invention, the semiconductor structure 100 comprises a substrate 102, a well 104, a first dielectric layer 106, an isothermal heating layer 108, a second dielectric layer 110 and an interconnection metal layer 112. Wherein, the well 104 is disposed in the substrate 102, and the well 104 can be, for example, an N-type well or a P-type well, but not limited thereto.

The isothermal heating layer 108 is disposed over the well 104. The first dielectric layer 106 is disposed between the isothermal heating layer 108 and the well 104 to isolate the isothermal heating layer 108 from the well 104. One of ordinary skill in the art will understand that the material of the first dielectric layer 106 can be silicon oxide, but not limited thereto.

According to an embodiment of the present invention, the material of the isothermal heating layer 108 has a high resistance. The material can be, for example, polysilicon, tungsten, a P-type well, an N-type well or BaTiO3, but not limited thereto.

The second dielectric layer 110 is disposed over the isothermal heating layer 108. One of ordinary skill in the art will understand that the second dielectric layer 110 can be silicon oxide, but not limited thereto.

The interconnection metal layer 112 is disposed over the second dielectric layer 110. The material of the interconnection metal layer 112 has a low resistance. The material can be, for example, aluminum or copper, but not limited thereto.

In this embodiment, the semiconductor structure 100 may further comprise a third dielectric layer 114, another isothermal heating layer 116, a fourth dielectric layer 118 and another interconnection metal layer 120. Wherein, the isothermal heating layer 116 is disposed over the interconnection metal layer 112. The third dielectric layer 114 is disposed between the isothermal heating layer 116 and the interconnection metal layer 112 to isolate the isothermal heating layer 116 from the interconnection metal layer 112.

The interconnection metal layer 120 is disposed over the isothermal heating layer 116. The fourth dielectric layer 118 is disposed between the isothermal heating layer 116 and the interconnection metal layer 120 to isolate the isothermal heating layer 116 from the interconnection metal layer 120.

In a preferred embodiment of the present invention, the material of the isothermal heating layer 116 has a high resistance. The material can be, for example, polysilicon, tungsten, a P-type well, an N-type well or BaTiO3, but not limited thereto.

In a preferred embodiment of the present invention, materials of the third dielectric layer 114 and the fourth dielectric layer 118 can be, for example, silicon oxide or other isolation materials, but not limited thereto.

In a preferred embodiment of the present invention, other film layers can be added in these film layers of the semiconductor structure 100 according to different requirements or manufacturing technology. The structure, therefore, is not limited to the semiconductor structure in FIG. 1.

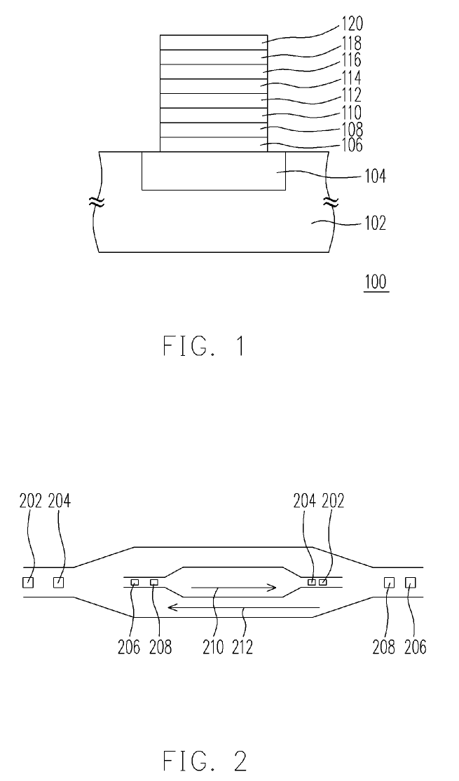

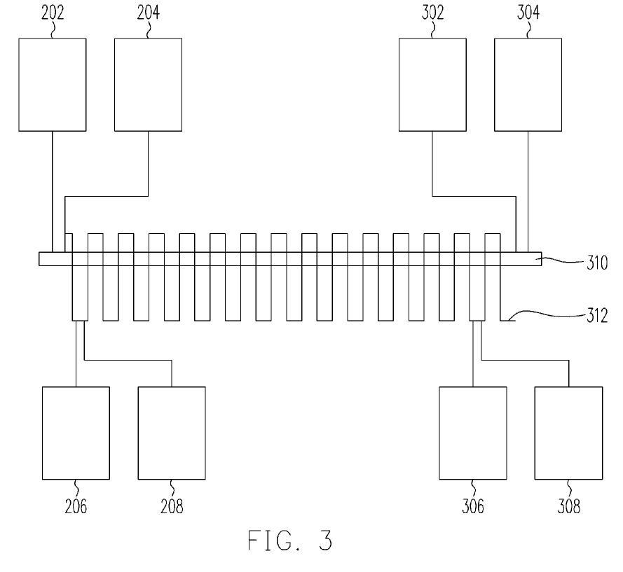

FIG. 2 is a configuration showing a top view of a semiconductor structure according to an embodiment of the present invention.

Referring to FIGS. 1 and 2, a testing current is applied to the interconnection metal layer 112 of the semiconductor structure 100 via area 202, or a testing voltage is applied to the interconnection metal layer via area 204, and an isothermal heating current is applied to the isothermal heating layer 116 via area 206 or an isothermal heating voltage is applied to the isothermal heating layer via area 208.

Because the isothermal heating current and the testing current flow in different layers, the isothermal heating current and the testing current generate their own electromagnetic fields. In this embodiment, an angle between the flow direction 210 of the testing current applied to the interconnection metal layer 112 and the flow direction 212 of the isothermal heating current applied to the isothermal heating layer 116 is shown in a top view in FIG. 2. One of ordinary skill in the art will know that, in order to reduce the electromagnetic effect of the testing current and the isothermal heating current, the angle can be, for example, 180° or 90°.

FIG. 3 is a top view showing a layout of the semiconductor structure according to an embodiment of the present invention.

Referring to FIG. 3, the layout of the semiconductor structure comprises testing areas 302, 304, 306 and 308, the testing-current application area 202, the testing-voltage application area 204, the isothermal-heating-current apply area 206, the isothermal-heating-voltage apply area 208, the isothermal heating layer 312 and the interconnection metal layer 310.

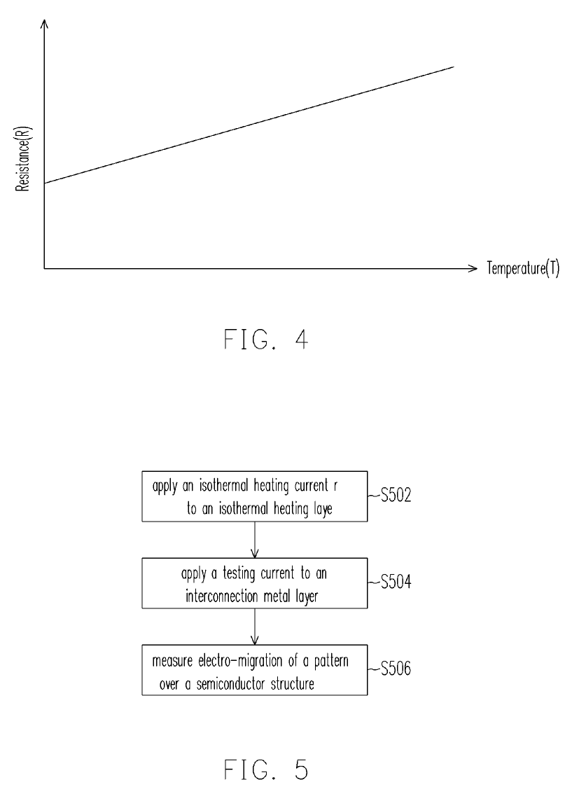

Referring to FIGS. 3 and 5, in the testing method, according to this embodiment of the present invention, first, an isothermal heating current is applied to the isothermal heating layer 312 for heating the isothermal heating layer 312 to a temperature corresponding to the isothermal heating current (at step s502). At step s504, a testing current is applied to the interconnection metal layer 310 and to make the resistance of the interconnection metal layer 310 to achieve a hoped resistance to obtain a resistance-temperature curve shown in FIG. 4.

The electro-migration of the interconnection metal layer can be measured via the testing areas 302, 304, 306 and 308 (at step s506).

Accordingly, the isothermal heating layer is adapted for heating the interconnection metal layer to predetermined testing temperatures for obtaining an accurate resistance-temperature curve. Therefore, the test result can be precise and the testing time can be reduced. Moreover, a lower level current can be used as the testing current.

Although the present invention has been described in terms of examplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A semiconductor structure suitable for testing the electro-migration of an interconnection metal layer, the semiconductor structure comprising:
a well, disposed in the substrate;
an isothermal heating layer, disposed over the well;
a first dielectric layer, disposed between the well and the isothermal heating layer;
an interconnection metal layer, disposed over the isothermal heating layer; and
a second dielectric layer, disposed between the isothermal heating layer and the interconnection metal layer.

2. The semiconductor structure of claim 1, wherein the isothermal heating layer is adapted for receiving an isothermal heating current.

3. The semiconductor structure of claim 1, wherein the interconnection metal layer is adapted for receiving a testing current.

4. The semiconductor structure of claim 1, wherein a material of the isothermal heating layer comprises polysilicon.

5. The semiconductor structure of claim 1, wherein a material of the isothermal heating layer comprises tungsten.

6. The semiconductor structure of claim 1, wherein a P-type well constitutes the isothermal heating layer.

7. The semiconductor structure of claim 1, wherein an N-type well constitutes the isothermal heating layer.

8. The semiconductor structure of claim 1, wherein the isothermal heating layer comprises BaTiO3.

9. The semiconductor structure of claim 1, wherein the interconnection metal layer comprises copper.

10. The semiconductor structure of claim 1, wherein the interconnection metal layer comprises aluminum.

11. A method of testing a semiconductor structure, the semiconductor structure at least comprising an isothermal heating layer and an interconnection metal layer, the method comprising:
applying an isothermal heating current to the isothermal heating layer;
applying a testing current to the interconnection metal layer; and
measuring electro-migration of the interconnection metal layer.

12. The testing method for a semiconductor structure of claim 11, wherein when the isothermal heating layer is heated to a predetermined temperature corresponding to the isothermal heating current and the resistance of the interconnection metal layer is achieved to a hoped resistance, the electro-migration of the interconnection metal layer can be measured via the testing areas.

13. The testing method for a semiconductor structure of claim 11, wherein directions of flow of the isothermal heating current and the testing current are formed an angle.

14. The testing method for a semiconductor structure of claim 13, wherein the angle is adjusted to reduce an electromagnetic effect of the isothermal heating current and the testing current.

15. The testing method for a semiconductor structure of claim 13, wherein the angle is 180°.

16. The testing method for a semiconductor structure of claim 13, wherein the angle is 90°.
